(19) United States
(12) Patent Application Publication
(10) Pub. No.: US 2026/0020293 A1
(43) Pub. Date: Jan. 15, 2026

(54) SEMICONDUCTOR DEVICE AND METHOD FOR MANUFACTURING SEMICONDUCTOR DEVICE

(71) Applicant: FUJI ELECTRIC CO., LTD., Kanagawa (JP)

(72) Inventors: Shuhei TATEMICHI, Matsumoto-city (JP); Tatsuya NAITO, Matsumoto-city (JP); Yasuhiko ONISHI, Matsumoto-city (JP)

(21) Appl. No.: 19/334,931

(22) Filed: Sep. 21, 2025

Related U.S. Application Data
(63) Continuation of application No. PCT/JP2024/036553, filed on Oct. 11, 2024.

(30) Foreign Application Priority Data
Oct. 13, 2023 (JP) 2023-177452

(51) Int. Cl. H10D 62/10; H10D 12/00; H10D 62/60; H10D 84/00; H10D 84/01

(52) U.S. Cl. CPC H10D 62/107; H10D 12/481; H10D 62/60; H10D 84/0109; H10D 84/161

(57) ABSTRACT

Provided is a semiconductor device including a transistor portion and a diode portion, the semiconductor device including: a drift region of a first conductivity type provided in a semiconductor substrate; and trench portions extending in a predetermined trench extension direction, wherein the transistor portion has a base region of a second conductivity type, emitter regions of the first conductivity type discretely provided in a trench extension direction, each having a higher doping concentration than the drift region, a contact region of the second conductivity type having a higher doping concentration than the base region, a trench contact portion extending from a front surface of the semiconductor substrate in a depth direction, in a mesa portion between two adjacent trench portions, and a thinning region provided between two adjacent emitter regions in the trench extension direction, and having a lower doping concentration of the second conductivity type than the contact region.

The contents of the following patent application(s) are incorporated herein by reference: NO. 2023-177452 filed in JP on Oct. 13, 2023 NO. PCT/JP2024/036553 filed in WO on Oct. 11, 2024.

### BACKGROUND

### 1. Technical Field

The present invention relates to a semiconductor device and a method for manufacturing a semiconductor device.

### 2. Related Art

In the related art, a semiconductor device including an IGBT region and a FWD region is known (for example, refer to Patent Documents 1, 2).
Patent Document 1: Japanese Patent Application Publication No. 2021-144998
Patent Document 2: Japanese Patent Application Publication No. 2022-181457

### BRIEF DESCRIPTION OF THE DRAWINGS

FIG. 1 shows an example of a semiconductor device 100 in a top plan view.

FIG. 2A is an enlarged view of a region A in FIG. 1.

FIG. 2B is a view showing an example of a cross section XZ including a cross section a-a′ in

FIG. 2A.

FIG. 3A shows an example of a cross section YZ including a cross section b-b′ in FIG. 2A.

FIG. 3B shows a modified example of the cross section YZ including the cross section b-b′ in FIG. 2A.

FIG. 3C shows a modified example of the cross section YZ including the cross section b-b′ in FIG. 2A.

FIG. 4A is a modified example of the enlarged view of the region A in FIG. 1.

FIG. 4B shows an example of a cross section YZ including a cross section d-d′ in FIG. 4A.

FIG. 4C shows a modified example of the cross section YZ including the cross section d-d′ in FIG. 4A.

FIG. 4D shows a modified example of the cross section YZ including the cross section d-d′ in FIG. 4A.

FIG. 4E shows a modified example of the cross section YZ including the cross section d-d′ in FIG. 4A.

FIG. 4F shows a modified example of the cross section YZ including the cross section d-d′ in FIG. 4A.

FIG. 4G shows a modified example of the cross section YZ including the cross section d-d′ in FIG. 4A.

FIG. 5A shows a modified example of a mesa portion 71 in the top plan view.

FIG. 5B shows a modified example of the mesa portion 71 in the top plan view.

FIG. 6A shows dependence of a switching loss Err during reverse recovery, on a ratio α.

FIG. 6B shows dependence of a saturation current Isat of a collector current, on the ratio α.

FIG. 7 shows an example of a method for manufacturing the semiconductor device 100.

### DESCRIPTION OF EXEMPLARY EMBODIMENTS

Hereinafter, the invention will be described through embodiments of the invention, but the following embodiments do not limit the invention according to claims. In addition, not all combinations of features described in the embodiments are essential to a solution of the invention.

As used herein, one side in a direction parallel to a depth direction of a semiconductor substrate is referred to as “upper” and another side is referred to as “lower”. One surface of two main surfaces of a substrate, a layer, or another member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components and do not limit a specific direction. For example, the Z axis is not limited to indicating a height direction relative to the ground. It should be noted that a +Z axis direction and a −Z axis direction are directions opposite to each other. When a Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, a direction of the Z axis may be referred to as the depth direction. In addition, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in fabrication or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is ND and the acceptor concentration is NA, the net doping concentration at any position is given as ND-NA. In the present specification, the net doping concentration may be simply referred to as the doping concentration.

In the present specification, a description of a P+ type or an N+ type means a higher doping concentration than that of the P type or the N type, and a description of a P-type or an N-type means a lower doping concentration than that of the P type or the N type. In addition, in the present specification, a description of a P++ type or an N++ type means a higher doping concentration than that of the P+ type or the N+ type.

In the present specification, a chemical concentration refers to an atomic density of impurities that are measured regardless of an electrical activation state. The chemical concentration can be measured by, for example, secondary ion mass spectrometry (SIMS). The net doping concentration described above can be measured by capacitance-voltage profiling (CV profiling). In addition, a carrier concentration that is measured by spreading resistance profiling (SRP method) may be set as the net doping concentration. A carrier means an electron charge carrier or a hole charge carrier. The carrier concentration measured by the CV profiling or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the region of the N type may be referred to as the donor concentration, and the doping concentration of the region of the P type may be referred to as the acceptor concentration.

In addition, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping.

The carrier concentration that is measured by the SRP method may be lower than the concentration of the donor or the acceptor. In a range where a current flows when a spreading resistance is measured, carrier mobility of the semiconductor substrate may be lower than a value in a crystalline state. The decrease in carrier mobility occurs when carriers are scattered due to disorder (disorder) of a crystal structure due to a lattice defect or the like. The carrier concentration decreases for the following reason. In the SRP method, a spreading resistance is measured, and the carrier concentration is converted from a measurement value of the spreading resistance. At this time, mobility of the crystalline state is used as the carrier mobility. On the other hand, despite the fact that the carrier mobility has decreased at a position where the lattice defect is introduced, the carrier concentration is calculated by using the carrier mobility of the crystalline state. Therefore, a value lower than an actual carrier concentration, that is, a concentration of the donor or the acceptor, is obtained.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. In the present specification, an SI unit system is adopted. In the present specification, a unit of a distance or length may be represented by cm (centimeter). In this case, various calculations may be converted into m (meter) to be calculated. As for numeric representation of power of 10, for example, the representation 1E+16 indicates 1×10¹⁶, and the representation 1E−16 indicates 1×10⁻¹⁶.

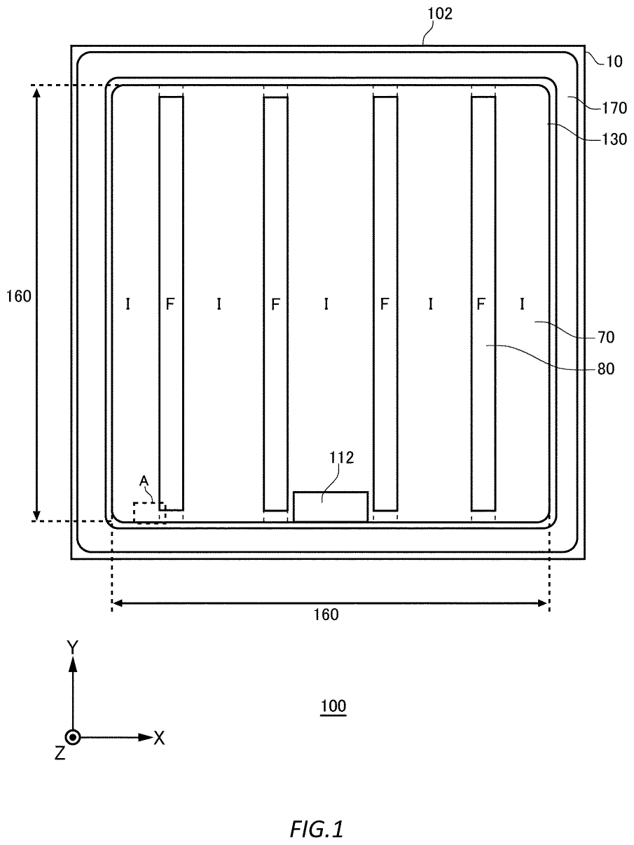

FIG. 1 shows an example of a semiconductor device 100 in a top plan view. FIG. 1 shows a position at which each member is projected onto an upper surface of a semiconductor substrate 10. FIG. 1 shows only some members of the semiconductor device 100, and illustration of some members is omitted. The semiconductor device 100 is a semiconductor chip including a transistor portion 70 and a diode portion 80.

The transistor portion 70 includes a transistor such as an IGBT (Insulated Gate Bipolar Transistor). The diode portion 80 includes a diode such as a free wheeling diode (FWD). The semiconductor device 100 in the present example is a reverse conducting IGBT (RC-IGBT) having the transistor portion 70 and the diode portion 80 on the same chip.

The semiconductor substrate 10 is a substrate which is formed of a semiconductor material. The semiconductor substrate 10 may be a silicon substrate, may be a silicon carbide substrate, may be a diamond substrate, may be a nitride semiconductor substrate of gallium nitride or the like, may be an inorganic compound semiconductor substrate of gallium oxide or the like, or may be an organic compound semiconductor substrate. The semiconductor substrate 10 in the present example is the silicon substrate. The semiconductor substrate 10 may be a wafer cut out from a semiconductor ingot, or may be a chip obtained by singulating the wafer. The semiconductor ingot may be manufactured by any of a Czochralski method (CZ method), a magnetic field applied Czochralski method (MCZ method), or a float zone method (FZ method).

A semiconductor substrate 10 has end sides 102 in a top view. When merely referred to as the top view in the present specification, it means that the semiconductor substrate 10 is viewed from an upper surface side. The semiconductor substrate 10 in the present example has two sets of end sides 102 facing each other in top view. In FIG. 1, the X axis and the Y axis are parallel to any of the end sides 102. In addition, the Z axis is perpendicular to the upper surface of the semiconductor substrate 10. The semiconductor substrate 10 includes an active portion 160 and an edge termination structure portion 170.

The active portion 160 is a region where a main current flows in the depth direction between the upper surface and a lower surface of the semiconductor substrate 10 during an operation of the semiconductor device 100. An emitter electrode is provided above the active portion 160, but is omitted in FIG. 1.

The active portion 160 is provided with at least one of the transistor portion 70 including a transistor element such as an IGBT, or the diode portion 80 including a diode element such as a free wheeling diode (FWD). In the example of FIG. 1, the transistor portion 70 and the diode portion 80 are alternately arranged along a predetermined array direction (the X axis direction in the present example) at the upper surface of the semiconductor substrate 10.

In FIG. 1, a region where the transistor portion 70 is arranged is indicated by a symbol “I”, and a region where the diode portion 80 is arranged is indicated by a symbol “F”. In the present specification, a direction perpendicular to the array direction in the top view may be referred to as an extension direction (the Y axis direction in FIG. 1). Each of the transistor portion 70 and the diode portion 80 may be elongated in the extension direction. In other words, a length of the transistor portion 70 in the Y axis direction is greater than its width in the X axis direction. Similarly, a length of the diode portion 80 in the Y axis direction is greater than its width in the X axis direction. The extension direction of the transistor portion 70 and the diode portion 80 may be the same as a longitudinal direction of each trench portion described below.

The diode portion 80 includes a cathode region of the N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. In a region other than the cathode region at the lower surface of the semiconductor substrate 10, a collector region of the P+ type may be provided.

The transistor portion 70 includes a collector region of the P+ type in a region in contact with the lower surface of the semiconductor substrate 10. In addition, in the transistor portion 70, an emitter region of the N type, a base region of the P type, and a gate structure having a gate conductive portion and a gate dielectric film are periodically arranged on an upper surface side of the semiconductor substrate 10.

The semiconductor device 100 may include one or more pads above the semiconductor substrate 10. The semiconductor device 100 in the present example has a gate pad 112. The semiconductor device 100 may include a pad such as an anode pad, a cathode pad, and a current detection pad. Each pad is arranged in a vicinity of the end side 102. The vicinity of the end side 102 refers to a region between the end side 102 and the emitter electrode in the top view. When the semiconductor device 100 is mounted, each pad may be connected to an external circuit via a wiring line such as a wire.

A gate potential is applied to the gate pad 112. The gate pad 112 is electrically connected to a conductive portion of a gate trench portion of the active portion 160. The semiconductor device 100 includes a gate runner 130 which connects the gate pad 112 to the gate trench portion.

The gate runner 130 is electrically connected to the gate conductive portion of the transistor portion 70 and applies a gate voltage to the transistor portion 70. The gate runner 130 is provided to enclose an outer periphery of the active portion 160 in the top view. The gate runner 130 is electrically connected to the gate pad 112 provided in the edge termination structure portion 170.

In addition, the semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 in the present example includes the edge termination structure portion 170 between the active portion 160 and the end side 102 in the top view. The edge termination structure portion 170 in the present example is arranged between the gate runner 130 and the end side 102. The edge termination structure portion 170 reduces an electric field concentration on the upper surface side of the semiconductor substrate 10. The edge termination structure portion 170 may include at least one of a guard ring, a field plate, or a RESURF which is annularly provided to enclose the active portion 160.

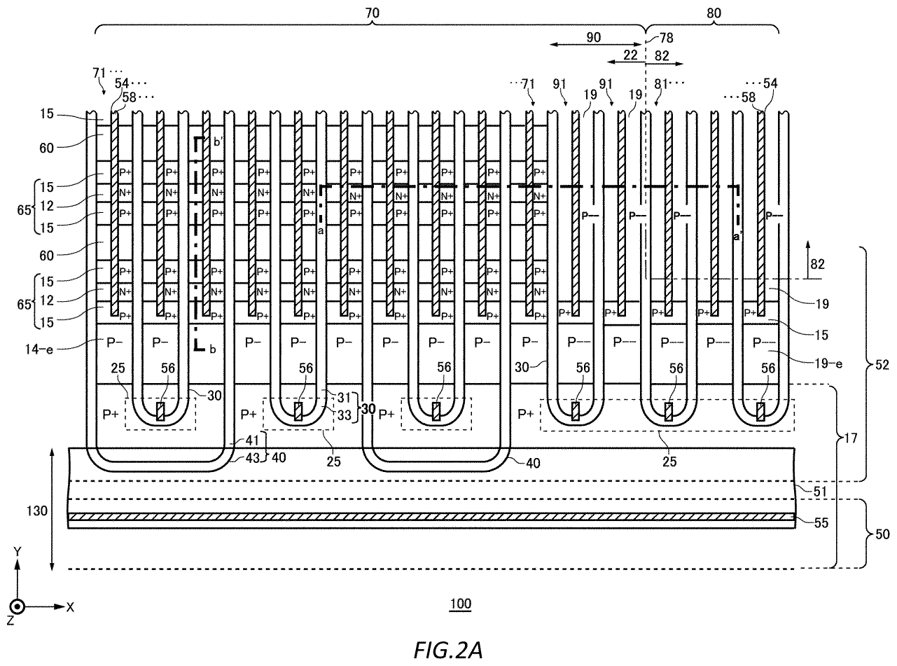

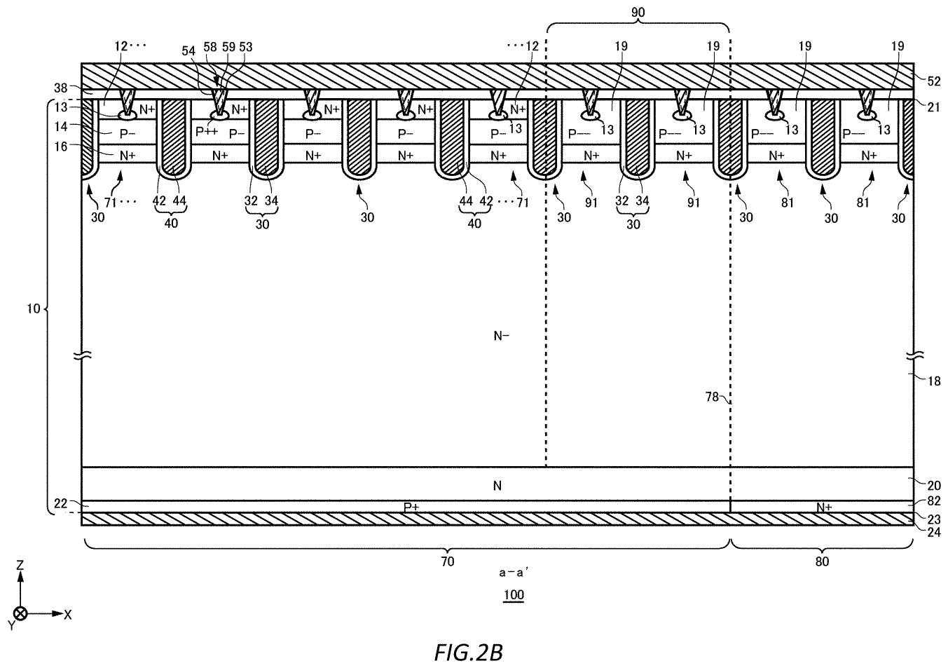

FIG. 2A is an enlarged view of a region A in FIG. 1. The region A is a region including the transistor portion 70, the diode portion 80, and the gate runner 130. The gate runner 130 in the present example includes a gate metal layer 50 and a gate runner portion 51.

A boundary region 90 is provided between the transistor portion 70 and the diode portion 80 at a front surface 21 of the semiconductor substrate 10. The front surface 21 of the semiconductor substrate 10 refers to one of the two main surfaces opposite to each other in the semiconductor substrate 10. The front surface 21 will be described below.

The semiconductor device 100 in the present example includes a gate trench portion 40, a dummy trench portion 30, a well region 17, an emitter region 12, a base region 14, a contact region 15, and an anode region 19 which are formed in a front surface 21 side of the semiconductor substrate 10. In addition, the semiconductor device 100 in the present example includes an emitter electrode 52 and the gate metal layer 50 which are provided above the front surface 21 of the semiconductor substrate 10. The emitter electrode 52 and the gate metal layer 50 are provided to be separate from each other.

An interlayer dielectric film is formed between the emitter electrode 52 and the gate metal layer 50, and the front surface 21 of the semiconductor substrate 10, but the interlayer dielectric film is omitted in FIG. 2A. In the interlayer dielectric film in the present example, a contact hole 54, a contact hole 55, and a contact hole 56 are formed to pass through the interlayer dielectric film.

The emitter electrode 52 is electrically connected, through the contact hole 54 which is opened to the interlayer dielectric film, to the emitter region 12, the contact region 15, the base region 14, and the anode region 19 at the front surface 21 of the semiconductor substrate 10. In addition, the emitter electrode 52 is connected to a dummy conductive portion in the dummy trench portion 30, through the contact hole 56. Between the emitter electrode 52 and the dummy conductive portion, a connection portion 25 formed of a conductive material such as polysilicon doped with impurities may be provided.

The gate metal layer 50 is in contact with the gate runner portion 51, through the contact hole 55. The gate runner portion 51 is formed of a semiconductor such as polysilicon doped with impurities. The gate runner portion 51 is connected to a gate conductive portion in the gate trench portion 40, at the front surface 21 of the semiconductor substrate 10.

The emitter electrode 52 and the gate metal layer 50 are formed of a material containing metal. At least a partial region of the emitter electrode 52 may be formed of metal such as aluminum (Al), or a metal alloy such as an aluminum-silicon alloy (AlSi) or an aluminum-silicon-copper alloy (AlSiCu). At least a partial region of the gate metal layer 50 may be formed of metal such as aluminum (Al), or a metal alloy such as an aluminum-silicon alloy (AlSi) or an aluminum-silicon-copper alloy (AlSiCu). The emitter electrode 52 and the gate metal layer 50 may have barrier metal formed of titanium, a titanium compound, or the like under a region formed of aluminum and the like. Further, each electrode may have a plug, which is formed by embedding tungsten or the like so as to be in contact with the barrier metal and aluminum or the like, in the contact hole.

The well region 17 is provided to overlap with the gate metal layer 50 and the gate runner portion 51. The well region 17 is provided to extend with a predetermined width also in a range that does not overlap with the gate metal layer 50 and the gate runner portion 51. The well region 17 in the present example is provided to be spaced apart from an end of the contact hole 54 in the Y axis direction to a gate metal layer 50 side. The well region 17 is a region of a second conductivity type which has a higher doping concentration than the base region 14. The base region 14 in the present example is of the P-type, and the well region 17 is of the P+ type.

Each of the transistor portion 70 and the diode portion 80 includes a plurality of trench portions arrayed in an array direction at the front surface 21 of the semiconductor substrate 10. In the transistor portion 70 in the present example, one or more gate trench portions 40 and one or more dummy trench portions 30 are alternately provided along the array direction. In the diode portion 80 in the present example, the plurality of dummy trench portions 30 are provided along the array direction. In the diode portion 80 in the present example, the gate trench portion 40 is not provided.

In the transistor portion 70, one or more gate trench portions 40 are arrayed at a predetermined interval along the array direction of each trench. The gate conductive portion inside the gate trench portion 40 is electrically connected to the gate metal layer 50 for a gate potential to be applied. In the transistor portion 70, one or more dummy trench portions 30 may be arrayed at a predetermined interval along the array direction. A potential different from the gate potential is applied to the dummy conductive portion inside the dummy trench portion 30. The dummy conductive portion in the present example is electrically connected to the emitter electrode 52 for an emitter potential to be applied.

In the transistor portion 70, one or more gate trench portions 40 and one or more dummy trench portions 30 may be formed alternately along the array direction. In addition, the dummy trench portions 30 are arrayed in the diode portion 80 and the boundary region 90 at a predetermined interval along the array direction. It should be noted that the transistor portion 70 may be constituted only by the gate trench portion 40 without the dummy trench portion 30 being provided.

The gate trench portion 40 in the present example may have two extension parts 41 extending along the extension direction perpendicular to the array direction (parts of a trench that are linear along the extension direction), and a connection part 43 connecting the two extension parts 41. The extension direction in FIG. 2A is the Y axis direction.

Preferably, at least a part of the connection part 43 is provided in a curved shape in the top view. By the connection part 43 connecting end portions of two extension parts 41 to each other in the Y axis direction, it is possible to reduce the electric field concentration at the end portions of the extension parts 41.

In the transistor portion 70, the dummy trench portion 30 is provided between the respective extension parts 41 of the gate trench portion 40. Between the respective extension parts 41, one dummy trench portion 30 may be provided, or a plurality of dummy trench portions 30 may be provided. The dummy trench portion 30 may have a linear shape extending in the extension direction, or may have extension parts 31 and a connection part 33 similar to the gate trench portion 40. The semiconductor device 100 may include both of the linear dummy trench portion 30 having no connection part 33, and the dummy trench portion 30 having the connection part 33. A direction in which the extension parts 41 of the gate trench portion 40 or the extension parts 31 of the dummy trench portion 30 extend to be long in the extension direction is referred to as a longitudinal direction of the trench portion. The longitudinal direction of the gate trench portion 40 or the dummy trench portion 30 may match the extension direction. In the present example, the extension direction and the longitudinal direction are the Y axis directions. The array direction in which the plurality of gate trench portions 40 or the plurality of dummy trench portions 30 are arrayed is referred to as a short direction of the trench portion. The short direction may match the array direction. The short direction may also be perpendicular to the longitudinal direction. In the present example, the short direction is perpendicular to the longitudinal direction. In the present example, the array direction and the short direction are the X axis directions.

In the connection part 43 at an edge of the gate trench portion 40, the gate conductive portion inside the gate trench portion 40 is connected to the gate runner portion 51. The gate trench portion 40 may be provided to protrude further than the dummy trench portion 30 toward a gate runner portion 51 side in the extension direction (the Y axis direction). The protrusion part of the gate trench portion 40 is connected to the gate runner portion 51.

A diffusion depth of the well region 17 may be deeper than depths of the gate trench portion 40 and the dummy trench portion 30. End portions of the gate trench portion 40 and the dummy trench portion 30 in the Y axis direction are provided in the well region 17 in the top view. In other words, the bottom in the depth direction of each trench portion is covered with the well region 17 at the end portion of each trench portion in the Y axis direction. This makes it possible to reduce the electric field concentration at the bottom portion of each trench portion.

A mesa portion is provided between the respective trench portions in the array direction. The mesa portion refers to a region sandwiched between two adjacent trench portions inside the semiconductor substrate 10. As an example, an upper end of the mesa portion is the upper surface of the semiconductor substrate 10. A depth position of a lower end of the mesa portion is the same as a depth position of a lower end of the trench portion. The mesa portion in the present example is provided to extend in the extension direction (the Y axis direction) along the trench portion, at the upper surface of the semiconductor substrate 10.

The boundary region 90 is provided on a diode portion 80 side in the transistor portion 70. That is, the boundary region 90 is provided to be adjacent to the diode portion 80 in the transistor portion 70. The boundary region 90 may be a region that has the dummy trench portion 30 and that is provided with a collector region 22 on a back surface side of the semiconductor substrate 10. Each of both ends of the mesa portion included in the boundary region 90, in a trench array direction, may be in contact with the dummy trench portion 30. The trench portions of the boundary region 90 may be all dummy trench portions 30. The boundary region 90 may include the gate trench portion 40. The boundary region 90 in the present example is not provided with the emitter region 12 of a first conductivity type, in the mesa portion on the front surface 21 side of the semiconductor substrate 10. The boundary region 90 may have the base region 14, or may have the anode region 19, at the front surface 21. The boundary region 90 may have the emitter region 12 or the contact region 15 at the front surface 21. The boundary region 90 in the present example has the anode region 19 and the contact region 15 at the front surface 21. It should be noted that FIG. 2A shows positions of the collector region 22 and a cathode region 82 provided on the back surface side of the semiconductor substrate 10 when projected onto the front surface 21 side.

A mesa portion 71 is a mesa portion provided in the transistor portion 70. A mesa portion 81 is a mesa portion provided in the diode portion 80. A mesa portion 91 is a mesa portion provided in the boundary region 90. As merely referred to as the mesa portion in the present specification, it may indicate each of the mesa portion 71, the mesa portion 81, or the mesa portion 91. The extension part of each trench portion may be defined as one trench portion. That is, a region sandwiched between two extension parts may be defined as a mesa portion.

Each mesa portion is provided with the base region 14 or the anode region 19. In the base region 14 or the anode region 19 exposed on the upper surface of the semiconductor substrate 10 in the mesa portion, a region arranged closest to the gate metal layer 50 is defined as a base region 14-e or an anode region 19-e. While the base region 14-e or the anode region 19-e arranged at one end portion of each mesa portion in the extension direction is shown in FIG. 2A, the base region 14-e or the anode region 19-e is also arranged at another end portion of each mesa portion. In each mesa portion, at least one of the emitter region 12 of the first conductivity type or the contact region 15 of the second conductivity type may be provided in a region sandwiched between the base regions 14-e or the anode regions 19-e in the top view. The emitter region 12 in the present example is the N+ type, and the contact region 15 is the P+ type. The emitter region 12 and the contact region 15 may be provided between the base region 14 and the upper surface of the semiconductor substrate 10 in the depth direction.

The mesa portion 71 of the transistor portion 70 includes the emitter region 12 exposed on the upper surface of the semiconductor substrate 10. The emitter region 12 is provided in contact with the gate trench portion 40. The mesa portion 71 in contact with the gate trench portion 40 may be provided with the contact region 15 exposed on the upper surface of the semiconductor substrate 10.

Each of the contact region 15 and the emitter region 12 in the mesa portion 71 is provided from one trench portion to another trench portion in the X axis direction. As an example, the contact region 15 and the emitter region 12 in the mesa portion 71 are alternately arranged along the trench extension direction (the Y axis direction).

The mesa portion 71 in the present example has a thinning region 60 and a non-thinning region 65. The thinning region 60 and the non-thinning region 65 are alternately arranged in the trench extension direction. The thinning region 60 will be described below.

The non-thinning region 65 has the emitter region 12 and the contact region 15. In the trench extension direction, one or more emitter regions and one or more contact regions are continuously and alternately arranged. At both ends of the non-thinning region 65 in the trench extension direction, the contact region 15 may be provided. That is, the emitter region 12 of the non-thinning region 65 may be sandwiched between two adjacent contact regions 15 in the trench extension direction. The number of repetitions of the emitter region 12 and the contact region 15 in the non-thinning region 65 is not limited to the present example. In the non-thinning region 65 in the present example, one emitter region 12 and two contact regions 15 are arranged continuously; however, two emitter regions 12 and three contact regions 15 may be arranged continuously, or three emitter regions 12 and four contact regions 15 may be arranged continuously.

The mesa portion 81 of the diode portion 80 is not provided with the emitter region 12, but may be provided with the emitter region 12. The anode region 19 is provided at an upper surface of the mesa portion 81. The contact region 15 may be provided at the upper surface of the mesa portion 81. A region sandwiched between the anode regions 19-e at the upper surface of the mesa portion 81 may be provided with the contact region 15 in contact with each of the anode regions 19-e. A region sandwiched between the contact regions 15 at an upper surface of the mesa portion 81 may be provided with the anode region 19. The anode region 19 may be arranged over the entire region sandwiched between the contact regions 15 in the trench extension direction.

The contact hole 54 is provided above each mesa portion. The contact hole 54 is arranged in a region sandwiched between the base regions 14-e or the anode regions 19-e along the trench extension direction. The contact hole 54 in the present example is provided above each region of the contact region 15, the base region 14, the anode region 19, and the emitter region 12. The contact hole 54 is not provided in regions corresponding to the base region 14-e, the anode region 19-e, and the well region 17. The contact hole 54 may be arranged at the center of the mesa portion 71 in the trench array direction (the X axis direction). A trench contact portion 58 is provided in the contact hole 54. The trench contact portion 58 will be described below.

In the diode portion 80, a region adjacent to the lower surface of the semiconductor substrate 10 is provided with the cathode region 82 of the N+ type. A doping concentration of the cathode region 82 is higher than a doping concentration of a drift region 18. The collector region 22 of the P+ type may be provided in a region, in which the cathode region 82 is not provided, in the lower surface of the semiconductor substrate 10. The cathode region 82 and the collector region 22 are provided between a back surface 23 of the semiconductor substrate 10 and a buffer region 20 which will be described below. In FIG. 2A, a boundary 78 between the cathode region 82 and the collector region 22 is indicated by a dashed line.

The cathode region 82 is arranged to be spaced apart from the well region 17 in the Y axis direction. This makes it possible to ensure a distance between a region of the P type (the well region 17) that has a comparatively high doping concentration and that is formed up to a deep position, and the cathode region 82, and to enhance a breakdown voltage and suppress hole injection from the well region 17. In the present example, an end portion of the cathode region 82 in the Y axis direction is arranged to be spaced away from the well region 17 further than an end portion of the contact hole 54 in the Y axis direction. In another example, the end portion of the cathode region 82 in the Y axis direction may be arranged between the well region 17 and the contact hole 54.

The anode region 19 is provided in the mesa portion 91 of the boundary region 90. The boundary region 90 may have a plurality of the mesa portions 91. The mesa portion 91 may have the base region 14 instead of the anode region 19. The anode region 19 will be described below.

FIG. 2B is a view showing an example of a cross section XZ including a cross section a-a′ in FIG. 2A. The cross section XZ including the cross section a-a′ is an XZ plane that passes through the emitter region 12 in the transistor portion 70. The semiconductor device 100 in the present example has the semiconductor substrate 10, an interlayer dielectric film 38, the emitter electrode 52, and a collector electrode 24, in the cross section XZ including the cross section a-a′. The emitter electrode 52 is formed above the semiconductor substrate 10 and the interlayer dielectric film 38.

The drift region 18 is a region of the first conductivity type which is provided in the semiconductor substrate 10. The drift region 18 in the present example is of the N-type as an example. The drift region 18 may be a region which has remained without another doping region formed in the semiconductor substrate 10. That is, the doping concentration of the drift region 18 may be a doping concentration of the semiconductor substrate 10.

The buffer region 20 is a region of the first conductivity type which is provided to be closer to a back surface 23 side of the semiconductor substrate 10 than the drift region 18. The buffer region 20 in the present example is provided to be closer to the back surface 23 of the semiconductor substrate 10 than the center of the semiconductor substrate 10 in the depth direction. The buffer region 20 in the present example is of the N type as an example. A doping concentration of the buffer region 20 is higher than the doping concentration of the drift region 18. The buffer region 20 may function as a field stop layer which prevents a depletion layer expanding from a lower surface side of the base region 14 from reaching the collector region 22 of the second conductivity type and the cathode region 82 of the first conductivity type.

The collector region 22 and the cathode region 82 are provided at the back surface 23 of the semiconductor substrate 10. The collector region 22 is provided below the buffer region 20 in the transistor portion 70. The cathode region 82 is provided below the buffer region 20 in the diode portion 80. The boundary 78 between the collector region 22 and the cathode region 82 may be a boundary between the transistor portion 70 and the diode portion 80.

The collector electrode 24 is formed at the back surface 23 of the semiconductor substrate 10. The collector electrode 24 is formed of a conductive material such as metal. At least a partial region of the collector electrode 24 may be formed of metal such as aluminum (Al), or a metal alloy such as an aluminum-silicon alloy (AlSi) or an aluminum-silicon-copper alloy (AlSiCu).

The base region 14 is a region of the second conductivity type which is provided above the drift region 18 in the mesa portion 71 and the mesa portion 91. The base region 14 is provided in contact with the gate trench portion 40. The base region 14 may be provided in contact with the dummy trench portion 30.

The anode region 19 is a region of the second conductivity type which is provided above the drift region 18 in the mesa portion 91 and the mesa portion 81. The anode region 19 is provided in contact with the dummy trench portion 30. The anode region 19 may be provided in contact with the gate trench portion 40. A doping concentration of the anode region 19 may be the same as that of the base region 14, or may be lower than that of the base region 14. A maximum value of the doping concentration of the anode region 19 may be smaller than, or may be equal to a maximum value of the doping concentration of the base region 14. The maximum value of the doping concentration of the anode region 19 in the present example is smaller than the maximum value of the doping concentration of the base region 14. In the depth direction of the semiconductor substrate 10, a depth of the anode region 19 may be deeper than, may be shallower than, or may be equal to a depth of the base region 14. The depth of the anode region 19 in the present example is substantially equal to the depth of the base region 14. An integrated value obtained by integrating the doping concentration of the anode region 19 along the depth direction of the semiconductor substrate 10 may be smaller than, or may be equal to an integrated value obtained by integrating the doping concentration of the base region 14. The integrated value of the doping concentration of the anode region 19 in the present example is smaller than the integrated value of the doping concentration of the base region 14.

The emitter region 12 is provided to be closer to the front surface 21 side than the drift region 18, and has a higher doping concentration than the drift region 18. The emitter region 12 in the present example is provided above the base region 14 in the mesa portion 71. The emitter region 12 may be provided in contact with the gate trench portion 40. The emitter region 12 may be in contact with, or may not be in contact with the dummy trench portion 30. It should be noted that the emitter region 12 may not be provided in the mesa portion 91.

The contact region 15 is provided above the base region 14 in the mesa portion 91. The contact region 15 is provided in contact with the gate trench portion 40 in the mesa portion 91. In another cross section, the contact region 15 may be provided at the front surface 21 in the mesa portion 71.

An accumulation region 16 is a region of the first conductivity type which is provided to be closer to the front surface 21 side of the semiconductor substrate 10 than the drift region 18. The accumulation region 16 in the present example is of the N+ type as an example. The accumulation region 16 is provided in the mesa portion 71. The accumulation region 16 may be provided in the mesa portion 81 and the mesa portion 91.

In addition, the accumulation region 16 is provided in contact with the gate trench portion 40. The accumulation region 16 may be in contact with, or may not be in contact with the dummy trench portion 30. A doping concentration of the accumulation region 16 is higher than the doping concentration of the drift region 18. By providing the accumulation region 16, it is possible to increase a carrier injection enhancement effect (IE effect), and to reduce an on-voltage of the transistor portion 70.

One or more gate trench portions 40 and one or more dummy trench portions 30 are provided at the front surface 21. Each trench portion is provided from the front surface 21 to the drift region 18. In a region provided with at least any of the emitter region 12, the base region 14, the contact region 15, or the accumulation region 16, each trench portion also passes through these regions to reach the drift region 18. A structure in which the trench portion passes through the doping region is not limited to a structure which is made by forming the doping region and then forming the trench portion in order. A structure in which the trench portion is formed and then the doping region is formed between the trench portions is also included in the structure in which the trench portion passes through the doping region.

The gate trench portion 40 has a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor at the inner wall of the gate trench. The gate conductive portion 44 is formed inside from the gate dielectric film 42, inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region facing the adjacent base region 14 on a mesa portion 71 side across the gate dielectric film 42, in the depth direction of the semiconductor substrate 10. When a predetermined voltage is applied to the gate conductive portion 44, a channel as an inversion layer of electrons is formed in an interfacial surface layer of the base region 14 that is in contact with the gate trench.

The dummy trench portion 30 may have a same structure as that of the gate trench portion 40. The dummy trench portion 30 has a dummy trench, a dummy dielectric film 32, and a dummy conductive portion 34 which are formed on the front surface 21 side. The dummy dielectric film 32 is formed to cover an inner wall of the dummy trench. The dummy conductive portion 34 is formed inside the dummy trench, and is formed inside from the dummy dielectric film 32. The dummy dielectric film 32 insulates the dummy conductive portion 34 from the semiconductor substrate 10. The dummy trench portion 30 is covered with the interlayer dielectric film 38 at the front surface 21.

The interlayer dielectric film 38 is provided on the front surface 21. The emitter electrode 52 is provided above the interlayer dielectric film 38. The interlayer dielectric film 38 is provided with one or more contact holes 54 for electrically connecting the emitter electrode 52 to the semiconductor substrate 10. Similarly, the contact hole 55 and contact holes 56 may be provided to pass through the interlayer dielectric film 38.

The trench contact portion 58 is provided to extend from the front surface 21 of the semiconductor substrate 10 in the depth direction of the semiconductor substrate 10, in the mesa portion between two adjacent trench portions, among the plurality of trench portions. The trench contact portion 58 may be provided to extend from an upper end of the interlayer dielectric film 38 to an inside of the semiconductor substrate 10. The trench contact portion 58 in the present example is provided in the contact hole 54. The trench contact portion 58 may have a plug portion 59. The plug portion 59 may be made of tungsten. The trench contact portion 58 may have a barrier metal 53 formed of titanium, a titanium compound, or the like.

A plug region 13 is a region of the second conductivity type which is provided at a lower end of the trench contact portion 58, and which has a higher doping concentration than the base region 14. The plug region 13 may be provided to extend in the trench extension direction, at the lower end of the trench contact portion 58. The plug region 13 may be provided at an entire surface of the lower end of the trench contact portion 58. The plug region 13 may be formed in a region overlapping with a region where the dopant of the first conductivity type is ion-implanted to form the emitter region 12, or may be formed in a region overlapping with a region where the dopant of the second conductivity type is ion-implanted to form the contact region 15. The plug region 13 may also be provided in the boundary region 90 and the diode portion 80.

The semiconductor device 100 in the present example does not have a lifetime control portion having a lifetime killer, but may have the lifetime control portion. The semiconductor device 100 may not have a lifetime killer region on the front surface 21 side from the center in the depth direction of the semiconductor substrate 10. By including the thinning region 60, it is possible for the semiconductor device 100 in the present example to suppress the hole injection without forming the lifetime control portion, and to reduce a switching loss Err during reverse recovery.

In addition, by including the trench contact portion 58, it is possible for the semiconductor device 100 in the present example to enhance latch-up withstand capability. In this way, by including the thinning region 60 and the trench contact portion 58, it is possible for the semiconductor device 100 to suppress a decrease in the latch-up withstand capability by providing the thinning region 60, and to reduce the switching loss Err during the reverse recovery.

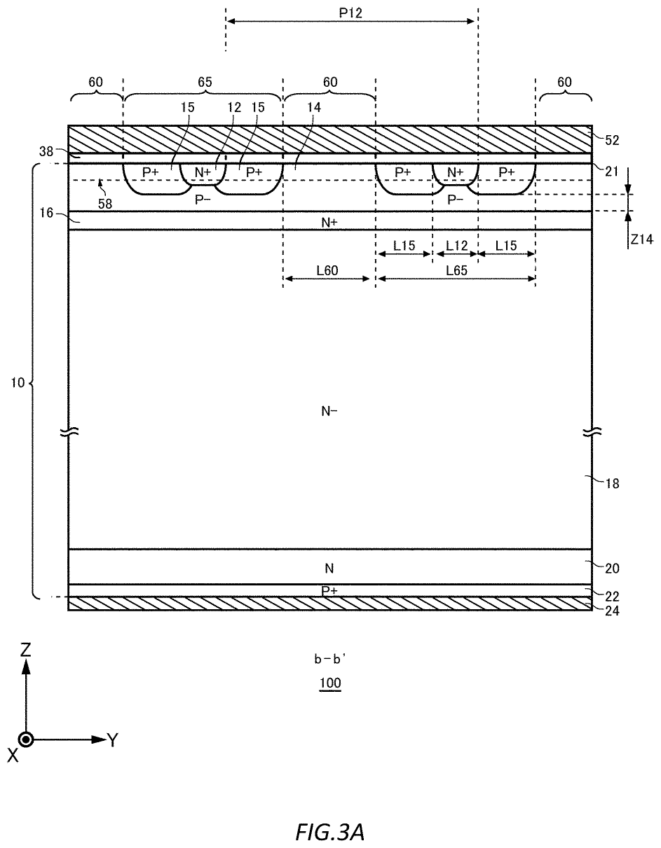

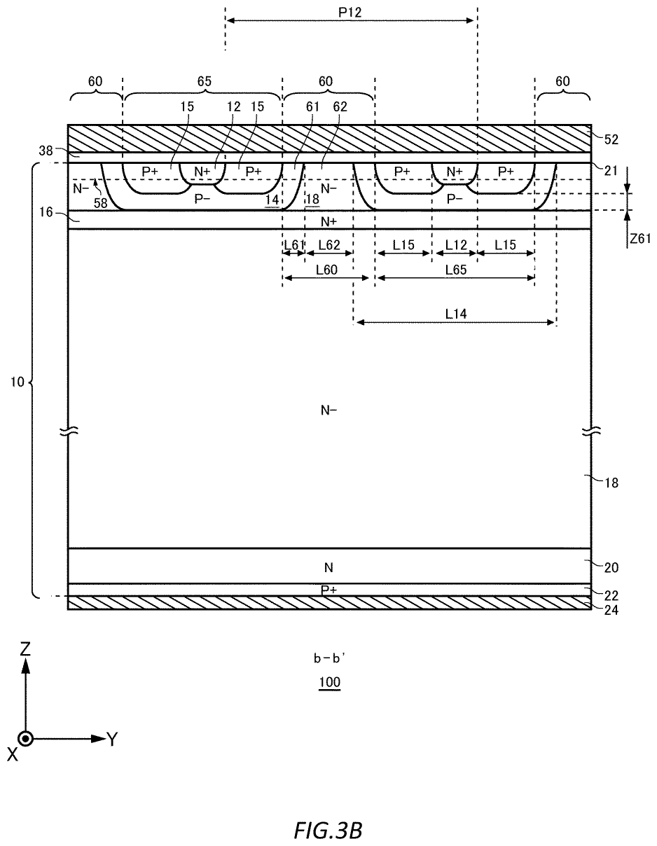

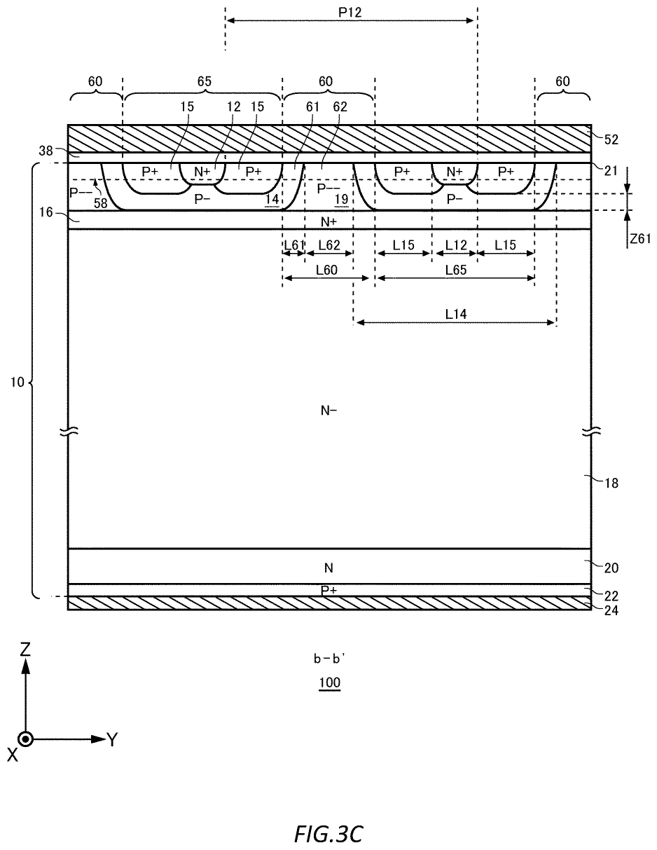

FIG. 3A shows an example of a cross section YZ including a cross section b-b′ in FIG. 2A. The cross section YZ including the cross section b-b′ is a YZ plane that passes through the mesa portion 71 of the transistor portion 70. The cross section b-b′ is a cross section that does not pass through the contact hole 54. The lower end of the trench contact portion 58 is indicated by a dashed line.

The thinning region 60 is provided between two adjacent non-thinning regions 65 in the trench extension direction. The thinning region 60 may be provided between two adjacent emitter regions 12 in the trench extension direction, among a plurality of emitter regions 12. In addition, the thinning region 60 may be provided between two adjacent contact regions 15 in the trench extension direction, among a plurality of contact regions 15.

The thinning region 60 may be of the first conductivity type, may be of the second conductivity type, or may include both of a region of the first conductivity type and a region of the second conductivity type. The thinning region 60 may have a doping concentration of the second conductivity type that is lower than that of the contact region 15. The doping concentration of the second conductivity type being lower may refer to the doping concentration of the second conductivity type being lower than that of the contact region 15 when the thinning region 60 is of the second conductivity type. In addition, when the thinning region 60 is of the first conductivity type, it may also refer to the doping concentration of the second conductivity type being lower than that of the contact region 15. The thinning region 60 may include at least one of the base region 14, the drift region 18, or the anode region 19. The thinning region 60 in the present example is the base region 14.

An interval P12 is an interval between two adjacent emitter regions 12 in the trench extension direction. The interval P12 may be an interval between the emitter region 12 of one non-thinning region 65 and the emitter region 12 of another non-thinning region 65, of two adjacent non-thinning regions 65. The interval P12 affects a saturation voltage of the transistor portion 70, a magnitude of the main current flowing through the transistor portion 70 during a short circuit, or the like, and thus may be determined according to a required electrical characteristic of the transistor portion 70.

A ratio α is a ratio of the interval P12 to a length L65 of the non-thinning region 65 in the trench extension direction. The ratio α may be 1.5 or more and 20 or less. The ratio α may be 2 or more, or may be 2.5 or more. The ratio α may be 5 or less, or may be 3 or less. The interval P12 may be 3 μm or more, and may be 10 μm or less. When the interval P12 becomes large and the region of the contact region 15 increases, a hole is easily injected; however, by providing the thinning region 60, it is possible to more effectively suppress the hole injection.

A length L15 is a length of the contact region 15 in the trench extension direction at the front surface 21. A length L12 is a length of the emitter region 12 in the trench extension direction at the front surface 21. The length L15 may be greater than the length L12.

A length L60 is a length of the thinning region 60 in the trench extension direction at the front surface 21. The length L65 is a length of the non-thinning region 65 in the trench extension direction at the front surface 21. The length L60 may be shorter, or may be longer than the length L65.

A thickness Z14 is a thickness of the base region 14 below the contact region 15. The thickness Z14 in the present example is a distance from a lower end of the contact region 15 to an upper end of the accumulation region 16 in the depth direction of the semiconductor substrate 10. The base region 14 in the present example covers a lower part and both of side surfaces of the non-thinning region 65.

It should be noted that the plurality of contact regions 15 may be provided at both ends of the emitter regions 12 in the trench extension direction. The contact region 15 may be in contact with the emitter region 12 at the front surface 21. When the emitter region 12 is not in contact with the contact region 15 at the front surface 21, a variation in a dimension of the emitter region 12 easily occurs due to an influence of diffusion of the implanted ions. On the other hand, by the emitter region 12 being in contact with the contact region 15 at the front surface 21, it is possible to determine the dimension of the emitter region 12 by a position of the contact region 15, and it becomes easy to reduce the variation in a saturation current.

The accumulation region 16 in the present example is provided above the drift region 18. The accumulation region 16 in the present example is provided between the base region 14 and the drift region 18, but may be omitted. The contact region 15 may cover an end portion of the emitter region 12 from a lower surface side in the extension direction. In this manner, a voltage drop when the hole passes through is reduced, and the latch-up is suppressed.

FIG. 3B shows a modified example of the cross section YZ including the cross section b-b′ in FIG. 2A. In the semiconductor device 100 in the present example, a structure of the thinning region 60 is different from that in the semiconductor device 100 in FIG. 3A. In the present example, a point different from the semiconductor device 100 in FIG. 3A is specifically described, while other points may be the same as the semiconductor device 100 in FIG. 3A. The thinning region 60 in the present example has a first thinning portion 61 and a second thinning portion 62.

The first thinning portion 61 is provided between two adjacent emitter regions 12. The first thinning portion 61 may be provided in contact with the contact region 15 at the front surface 21 of the semiconductor substrate 10. The thinning region 60 may have a plurality of first thinning portions 61 with the second thinning portion 62 sandwiched therebetween in the trench extension direction. The first thinning portion 61 may be the base region 14, or may be the anode region 19. The first thinning portion 61 in the present example is the base region 14.

The second thinning portion 62 is provided between two adjacent emitter regions 12, and is provided in contact with the first thinning portion 61 at the front surface 21. A doping concentration of the second thinning portion 62 is different from a doping concentration of the first thinning portion 61. The second thinning portion 62 may be provided between two adjacent first thinning portions 61 in the trench extension direction, among the plurality of first thinning portions 61, at the front surface 21. The second thinning portion 62 in the present example has the first conductivity type with a lower doping concentration than that of the emitter region 12. The second thinning portion 62 in the present example is the drift region 18. In the present example, in the trench extension direction, the drift region 18 that is the second thinning portion 62 is provided between the plurality of base regions 14 that are the first thinning portions 61. A length L14 is a length of the base region 14 in the trench extension direction. The length L14 may be greater than the length L65. The second thinning portion 62 may be sandwiched between the first thinning portions 61 along the extension direction of the gate trench portion 40.

The contact region 15 is provided between the emitter region 12 and the first thinning portion 61 which are adjacent to each other in the trench extension direction. At the front surface 21, one end of the contact region 15 may be in contact with the emitter region 12, and another end of the contact region 15 may be in contact with the first thinning portion 61. The first thinning portion 61 may be provided below the contact region 15. The first thinning portion 61 in the present example covers a side surface and a bottom surface of the contact region 15.

When the drift region 18 of the second thinning portion 62 is in direct contact with the contact region 15, the electric field strength increases, and thus by the first thinning portion 61 being sandwiched between the second thinning portion 62 and the contact region 15, it is possible to reduce the electric field strength.

The length L60 is a length of the thinning region 60 provided at the front surface 21 in the trench extension direction. A length L61 is a length of the first thinning portion 61 provided at the front surface 21 in the trench extension direction. A thickness Z61 is a thickness of the first thinning portion 61 provided below the contact region 15 in the depth direction of the semiconductor substrate 10. The length L61 may be greater than or equal to the thickness Z61. The length L61 may be 0.1 μm or more and 2.0 μm or less. In this way, by adjusting the length L61, it is possible to reduce the electric field concentration at the side surface of the contact region 15, and to enhance the electric field strength.

The length L61 is a length of the first thinning portion 61 in the trench extension direction at the front surface 21. A length L62 is a length of the second thinning portion 62 in the trench extension direction at the front surface 21. At the front surface 21, the length L62 of the second thinning portion 62 in the trench extension direction may be greater than the length L61 of the first thinning portion 61 in the trench extension direction. At the front surface 21, the length L62 of the second thinning portion 62 in the trench extension direction may be greater than the length L12 of the emitter region 12 in the trench extension direction.

FIG. 3C shows a modified example of the cross section YZ including the cross section b-b′ in FIG. 2A. In the semiconductor device 100 in the present example, a structure of the second thinning portion 62 is different from that in the semiconductor device 100 in FIG. 3B. In the present example, a point different from the semiconductor device 100 in FIG. 3B is specifically described, while other points may be the same as the semiconductor device 100 in FIG. 3B.

The second thinning portion 62 may have the second conductivity type with a lower doping concentration than that of the base region 14. The second thinning portion 62 in the present example is the anode region 19. The anode region 19 is of a P--type in an example. By setting the second thinning portion 62 to be the anode region 19 with a lower doping concentration than that of the base region 14, it is possible to suppress the hole injection more than in a case where the second thinning portion 62 is the base region 14.

Lower ends of the first thinning portion 61 and the second thinning portion 62 may be at the same depth position. In the present example, a lower end of the anode region 19 that is the second thinning portion 62 coincides with a lower end of the base region 14. The lower end of the anode region 19 that is the second thinning portion 62 may be at the upper end of the accumulation region 16.

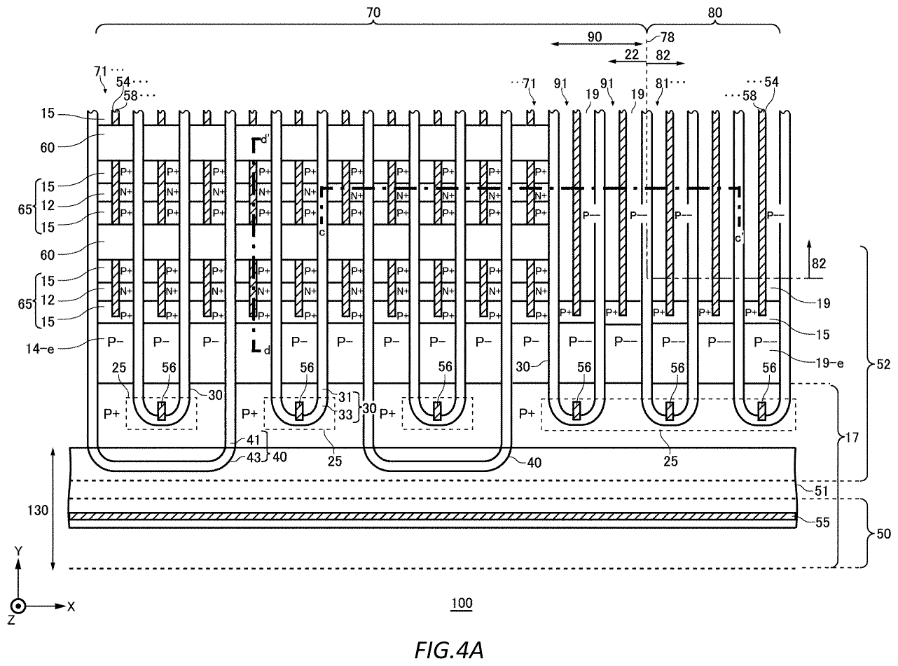

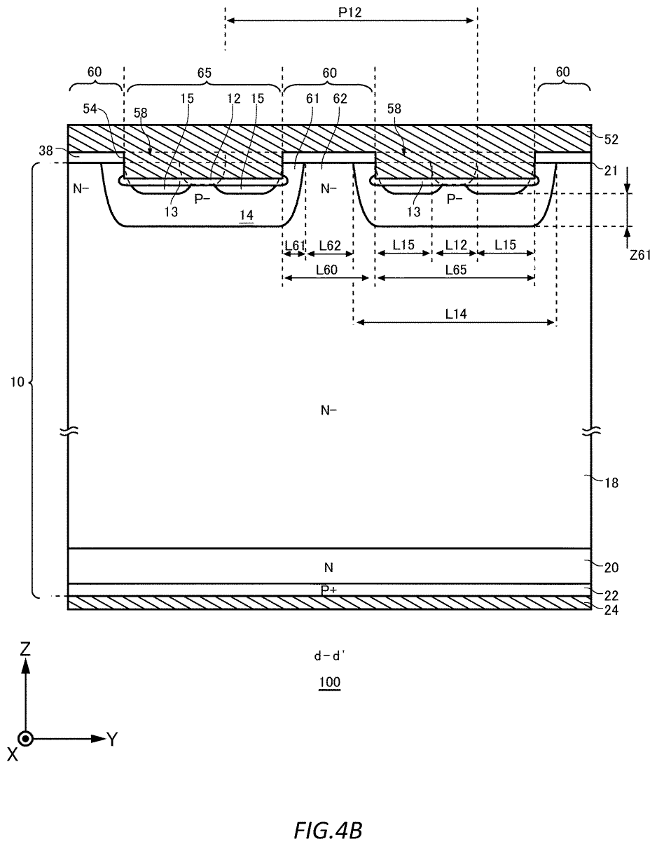

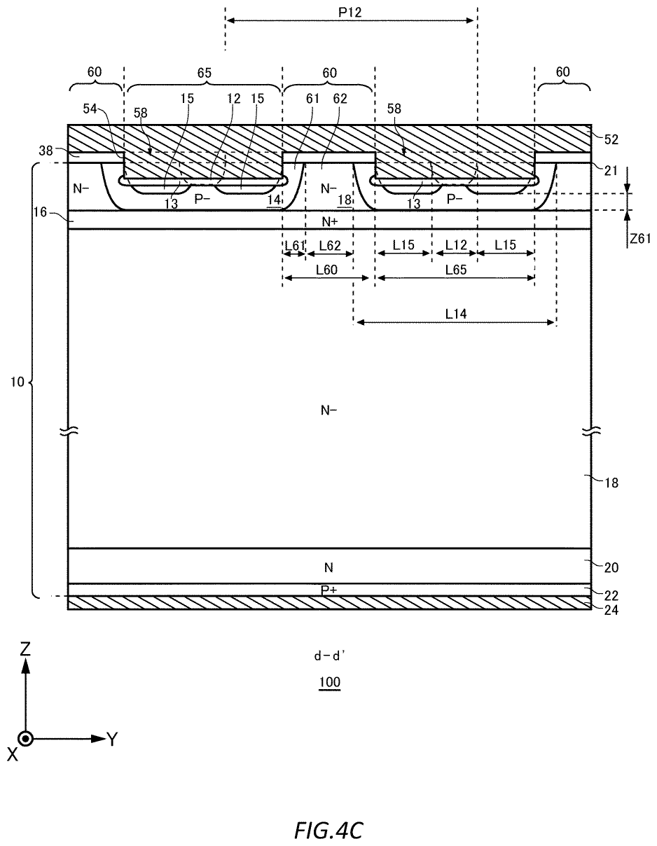

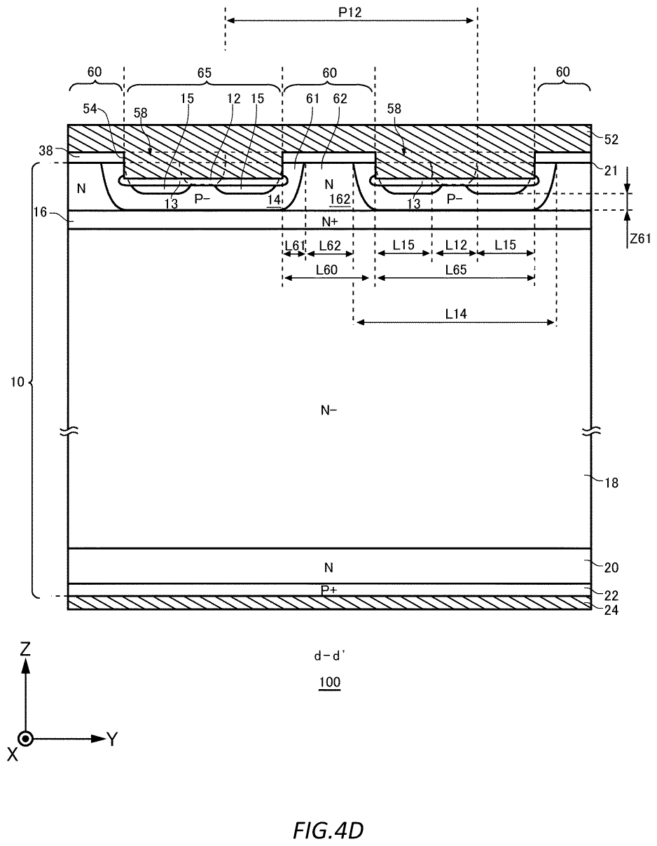

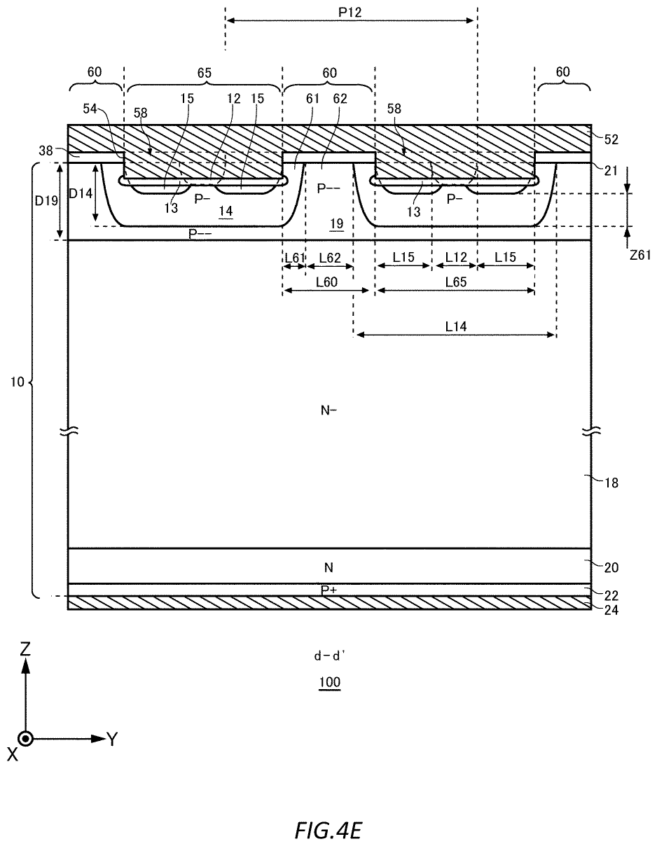

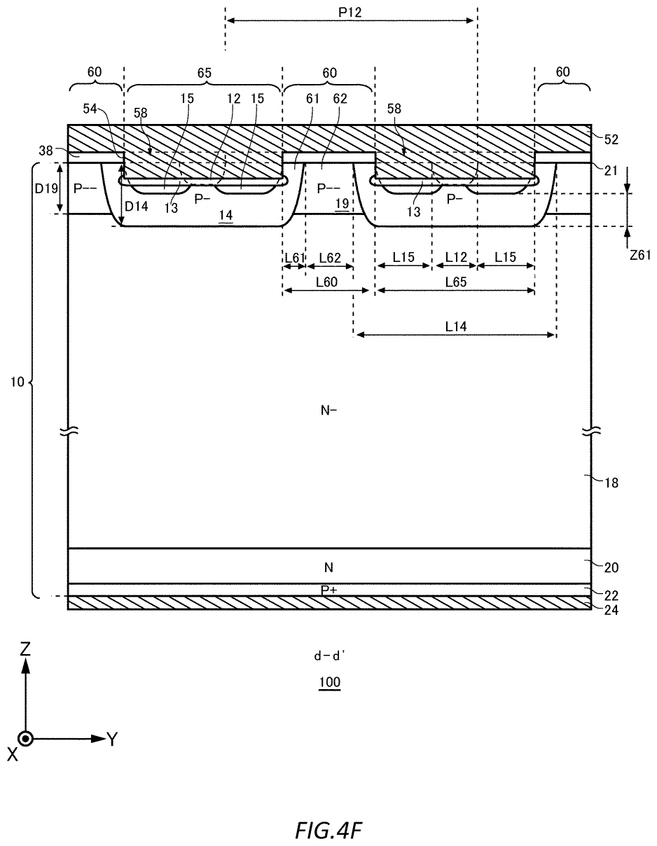

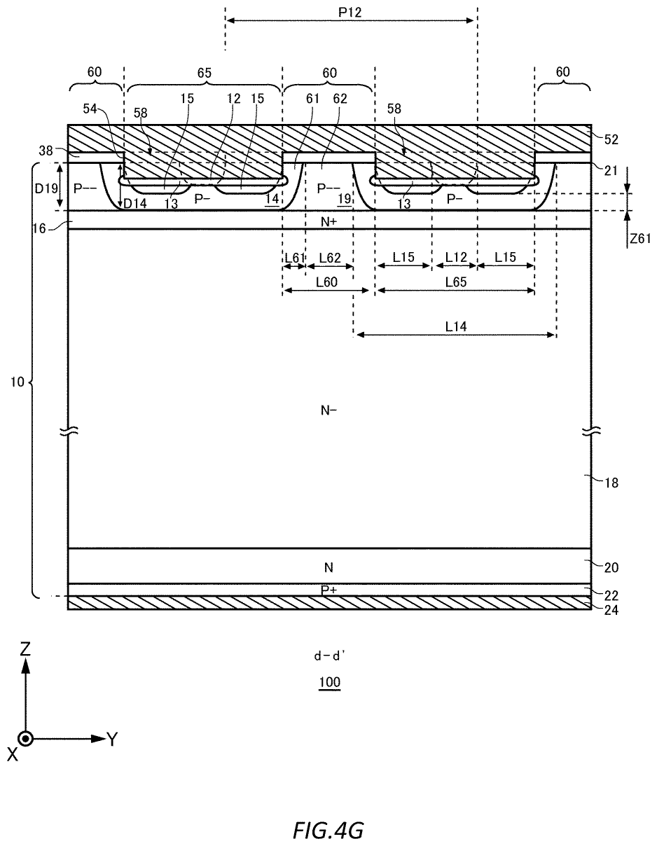

FIG. 4A is a modified example of the enlarged view of the region A in FIG. 1. In the semiconductor device 100 in the present example, a position for providing the contact hole 54 is different from that in the semiconductor device 100 in FIG. 2A. In the present example, a point different from the semiconductor device 100 in FIG. 2A is specifically described, while other points may be the same as the semiconductor device 100 in FIG. 2A. A structure of a cross section c-c′ may be the same as, or may be different from a structure of the cross section a-a′ in FIG. 2A.

The contact hole 54 in the present example is provided above the non-thinning region 65, but is not provided above the thinning region 60. Similarly, the trench contact portion 58 in the present example is provided above the non-thinning region 65, but is not provided above the thinning region 60. The regions for forming the contact hole 54 and the trench contact portion 58 may be the same as each other.

The trench contact portion 58 may be formed by using the interlayer dielectric film 38 as a mask. When the trench contact portion 58 is formed by using the interlayer dielectric film 38 as a mask, in the top view, the region where the contact hole 54 is provided may be a trench contact forming region, and in the top view, a region where the contact hole 54 is not provided may be a trench contact non-forming region. It should be noted that in the present specification, in the top view, the region where the trench contact portion 58 is provided is referred to as the trench contact forming region, and in the top view, the region where the trench contact portion 58 is not provided is referred to as the trench contact non-forming region.

Similarly, the plug region 13 may be formed by using the interlayer dielectric film 38 as a mask. When the plug region 13 is formed by using the interlayer dielectric film 38 as a mask, in the top view, the plug region 13 is formed in the region where the contact hole 54 is provided; however, the plug region 13 is not formed in the region where the contact hole 54 is not provided. In the present example, the thinning region 60 is not provided with the contact hole 54, and thus the thinning region 60 may not be provided with the plug region 13. By not providing the plug region 13 in the thinning region 60, it becomes easy to further suppress the hole injection.

Here, when the contact hole 54 is provided in the thinning region 60, a Schottky junction may be formed to increase a leakage current. In the semiconductor device 100 in the present example, the thinning region 60 is not provided with the contact hole 54, in the mesa portion 71, and thus it becomes easy to suppress the leakage current from the thinning region 60.

FIG. 4B shows an example of a cross section YZ including a cross section d-d′ in FIG. 4A. The cross section YZ including the cross section d-d′ is a YZ plane that passes through the mesa portion 71 of the transistor portion 70. The cross section d-d′ is a cross section that passes through the contact hole 54. The thinning region 60 in the present example has the base region 14 as the first thinning portion 61, and has the drift region 18 as the second thinning portion 62, similar to FIG. 3B. The semiconductor device 100 in the present example does not include the accumulation region 16, but may include the accumulation region 16.

The semiconductor device 100 in the present example includes the plug region 13 below the trench contact portion 58. The plug region 13 may extend from one end to another end of the trench contact portion 58 in the trench extension direction, below the trench contact portion 58. The plug region 13 may be provided in contact with a side wall of the trench contact portion 58 at an end portion of the trench contact portion 58 in the trench extension direction. The plug region 13 in the present example is provided in the non-thinning region 65, but may partially be provided in the thinning region 60.

The interlayer dielectric film 38 is provided above the thinning region 60 of the front surface 21. The interlayer dielectric film 38 in the present example is provided above the first thinning portion 61 and the second thinning portion 62. The interlayer dielectric film 38 in the present example covers both of the first thinning portion 61 and the second thinning portion 62 which are provided at the front surface 21. On the other hand, the interlayer dielectric film 38 has the contact hole 54 formed above the non-thinning region 65, and does not cover the non-thinning region 65 in the cross section d-d′.

The semiconductor device 100 in the present example does not have a Schottky junction in which the drift region 18 that is the second thinning portion 62 and the emitter electrode 52 are in contact, and thus it becomes easy to suppress the leakage current. It should be noted that in the present example, the contact hole 54 and the trench contact portion 58 are provided only above the non-thinning region 65, but may be provided above the first thinning portion 61, or may be provided above the second thinning portion 62.

FIG. 4C shows a modified example of the cross section YZ including the cross section d-d′ in FIG. 4A. The semiconductor device 100 in the present example includes the accumulation region 16, which is a difference from the semiconductor device 100 in FIG. 4B. In the present example, a point different from the semiconductor device 100 in FIG. 4B is specifically described, while other points may be the same as the semiconductor device 100 in FIG. 4B.

The accumulation region 16 is provided to extend in the trench extension direction, below the thinning region 60 and the non-thinning region 65 which are repeatedly arrayed in the trench extension direction. The lower end of the base region 14 is provided in contact with the upper end of the accumulation region 16. The lower end of the second thinning portion 62 that is the drift region 18 is provided in contact with the upper end of the accumulation region 16. The lower end of the base region 14 may be the same as the lower end of the second thinning portion 62 that is the drift region 18. It should be noted that the accumulation region 16 in the present example is provided below both of the thinning region 60 and the non-thinning region 65, but may be provided below only any one of them.

FIG. 4D shows a modified example of the cross section YZ including the cross section d-d′ in FIG. 4A. The semiconductor device 100 in the present example includes a first conductivity type region 162 as the second thinning portion 62, which is a difference from the semiconductor device 100 in FIG. 4C. In the present example, a point different from the semiconductor device 100 in FIG. 4C is specifically described, while other points may be the same as the semiconductor device 100 in FIG. 4C.

The first conductivity type region 162 is a region of the first conductivity type which has a higher doping concentration than the drift region 18. The first conductivity type region 162 may be formed, separately from the accumulation region 16, by ion-implanting the dopant of the first conductivity type. The dopant of the first conductivity type for forming the first conductivity type region 162 may be selectively ion-implanted by using a mask. The dopant of the first conductivity type for forming the first conductivity type region 162 may be selectively ion-implanted only into the region for forming the second thinning portion 62. The dopant of the first conductivity type for forming the first conductivity type region 162 may also be ion-implanted into a region other than the second thinning portion 62, such as the first thinning portion 61 or the non-thinning region 65.

FIG. 4E shows a modified example of the cross section YZ including the cross section d-d′ in FIG. 4A. The semiconductor device 100 in the present example includes the anode region 19 as the second thinning portion 62, which is a difference from the semiconductor device 100 in FIG. 4B. In the present example, a point different from the semiconductor device 100 in FIG. 4B is specifically described, while other points may be the same as the semiconductor device 100 in FIG. 4B.

The anode region 19 may be provided between two adjacent base regions 14 in the trench extension direction. The base region 14 and the anode region 19 may be formed by ion-implanting the dopant for forming the anode region 19 over the entire surface of the mesa portion 71, and then selectively ion-implanting the dopant for forming the base region 14. It should be noted that the base region 14 and the anode region 19 may be formed by selectively ion-implanting the dopant for forming the anode region 19 into the region for forming the anode region 19, and then selectively ion-implanting the dopant for forming the base region 14 into the region for forming the base region 14.

A depth D19 is a distance from the front surface 21 to the lower end of the anode region 19 in the depth direction of the semiconductor substrate 10. A depth D14 is a distance from the front surface 21 to the lower end of the base region 14 in the depth direction of the semiconductor substrate 10. The depth D19 may be greater than the depth D14. That is, the lower end of the anode region 19 may be deeper than the lower end of the base region 14 in the depth direction of the semiconductor substrate 10. The lower end of the anode region 19 may be deeper than lower ends of the emitter region 12 and the contact region 15 in the depth direction of the semiconductor substrate 10. The lower end of the anode region 19 may be deeper than the lower end of the trench contact portion 58 in the depth direction of the semiconductor substrate 10.

FIG. 4F shows a modified example of the cross section YZ including the cross section d-d′ in FIG. 4A. In the semiconductor device 100 in the present example, the depth of the anode region 19 is different from that of the semiconductor device 100 in FIG. 4E. In the present example, a point different from the semiconductor device 100 in FIG. 4E is specifically described, while other points may be the same as the semiconductor device 100 in FIG. 4E.

The depth D19 is smaller than the depth D14. That is, the lower end of the anode region 19 may be shallower than the lower end of the base region 14 in the depth direction of the semiconductor substrate 10. The lower end of the anode region 19 may be deeper than the lower ends of the emitter region 12 and the contact region 15 in the depth direction of the semiconductor substrate 10. The lower end of the anode region 19 may be deeper than the lower end of the trench contact portion 58 in the depth direction of the semiconductor substrate 10.

FIG. 4G shows a modified example of the cross section YZ including the cross section d-d′ in FIG. 4A. The semiconductor device 100 in the present example includes the accumulation region 16, which is a difference from the semiconductor device 100 in FIG. 4F. In the present example, a point different from the semiconductor device 100 in FIG. 4F is specifically described, while other points may be the same as the semiconductor device 100 in FIG. 4F.

The accumulation region 16 is provided to extend in the trench extension direction, below the thinning region 60 and the non-thinning region 65 which are repeatedly arrayed in the trench extension direction. The lower end of the base region 14 is provided in contact with the upper end of the accumulation region 16. The lower end of the anode region 19 is provided in contact with the upper end of the accumulation region 16. In this manner, the lower end of the base region 14 may be the same as the lower end of the anode region 19. It should be noted that the accumulation region 16 in the present example is provided below both of the thinning region 60 and the non-thinning region 65, but may be provided below only any one of them.

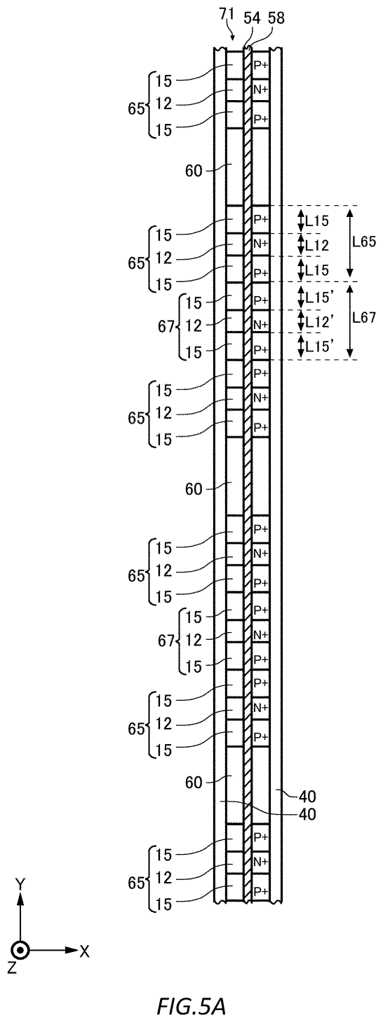

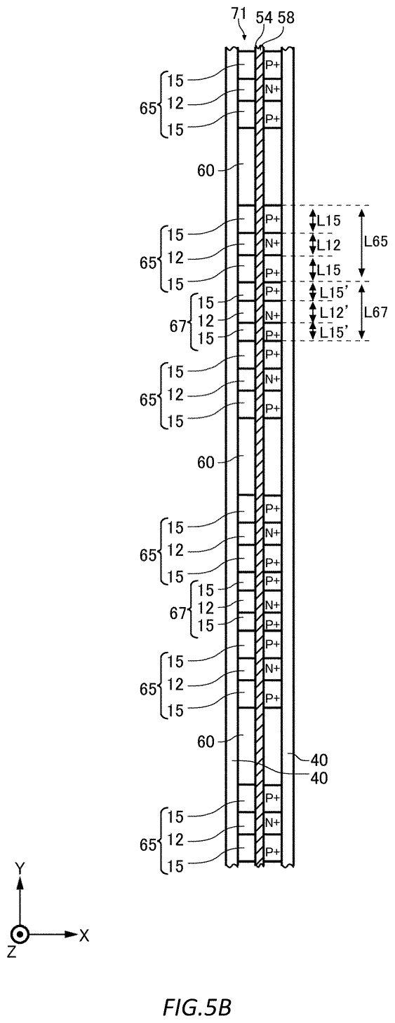

FIG. 5A shows a modified example of the mesa portion 71 in the top plan view. The present example shows an example of the structure of the mesa portion 71, which may be adopted for the mesa portion 71 of another semiconductor device 100. The semiconductor device 100 in the present example includes a non-thinning region 67.

The non-thinning region 67 is a region where some thinning region 60 among the plurality of thinning regions 60 which are regularly arrayed in the trench extension direction, is changed into the non-thinning region 65. The non-thinning region 67 includes the emitter region 12 and the contact region 15. In the present example, the emitter region 12 of the non-thinning region 67 is sandwiched between two adjacent contact regions 15 in the trench extension direction. The non-thinning region 67 in the present example has the same structure as that of the non-thinning region 65, but may have a different structure. In the non-thinning region 67, a doping concentration of each region and a width of each region in the trench extension direction may be the same as those of the non-thinning region 65.

A length L67 is a length of the non-thinning region 67 in the trench extension direction at the front surface 21. The length L67 may be the same as, or may be different from the length L65. The length L67 in the present example is the same as the length L65.

A length L12′ of the emitter region 12 in the non-thinning region 67 may be the same as, or may be different from the length L12 of the emitter region 12 in the non-thinning region 65. The length L12′ of the emitter region 12 in the non-thinning region 67 in the present example is the same as the length L12 of the emitter region 12 in the non-thinning region 65. A length L15′ of the contact region 15 in the non-thinning region 67 may be the same as, or may be different from the length L15 of the contact region 15 in the non-thinning region 65. The length L15′ of the contact region 15 in the non-thinning region 67 in the present example is the same as the length L15 of the contact region 15 in the non-thinning region 65.

FIG. 5B shows a modified example of the mesa portion 71 in the top plan view. The present example shows an example of the structure of the mesa portion 71, which may be adopted for the mesa portion 71 of another semiconductor device 100. In the mesa portion 71 in the present example, a structure of the non-thinning region 67 is different from that in the mesa portion 71 in FIG. 5A. In the present example, a point different from the mesa portion 71 in FIG. 5A is specifically described, while other points may be the same as the mesa portion 71 in FIG. 5A.

The non-thinning region 67 has a structure different from that of the non-thinning region 65. In the non-thinning region 67, at least one of the doping concentration of each region or the width of each region in the trench extension direction may be different from that of the non-thinning region 65. Each region in the non-thinning region 67 in the present example has the same doping concentration as each region in the non-thinning region 65, but may have a different doping concentration.

The length L15′ of the contact region 15 in the non-thinning region 67 is different from the length L15 of the contact region 15 in the non-thinning region 65. The length L15′ of the contact region 15 in the non-thinning region 67 in the present example is smaller than the length L15 of the contact region 15 in the non-thinning region 65, but may be greater. On the other hand, the length L12′ of the emitter region 12 in the non-thinning region 67 in the present example is the same as the length L12 of the emitter region 12 in the non-thinning region 65, but may be different. The length L12′ of the emitter region 12 in the non-thinning region 67 may be greater, or may be smaller than the length L12 of the emitter region 12 in the non-thinning region 65. In addition to adjusting an area of the contact region 15 by providing the thinning region 60, by adjusting the area of the contact region 15 in the non-thinning region 67, it becomes easy to adjust a magnitude of the hole injection.

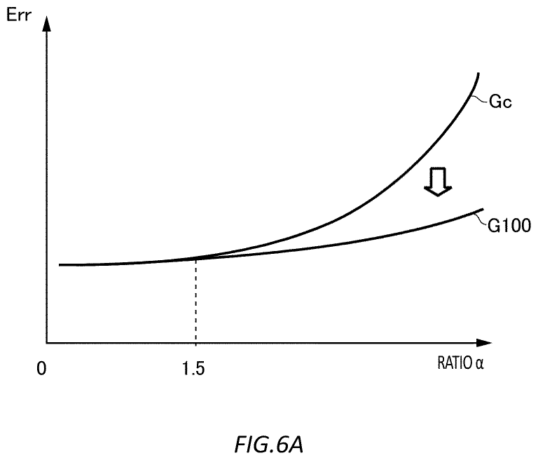

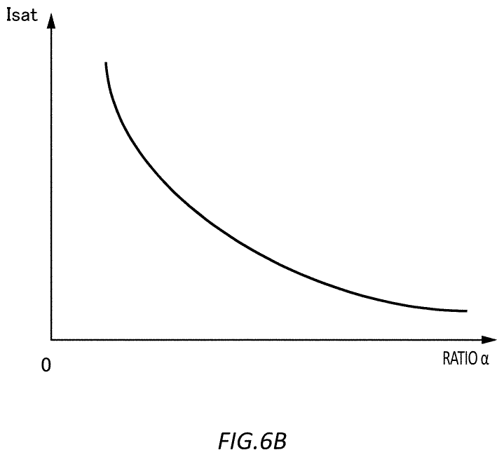

FIG. 6A shows dependence of a switching loss Err during reverse recovery, on a ratio α. A vertical axis represents the switching loss Err (a.u.) during the reverse recovery, and a horizontal axis represents the ratio α. A graph Gc shows a characteristic of the semiconductor device in the comparative example, and a graph G100 shows a characteristic of the semiconductor device 100. The semiconductor device in the comparative example is a semiconductor device which does not include the thinning region 60. When the ratio α of the interval P12 to the length L65 of the non-thinning region 65 in the trench extension direction, becomes great, there is a tendency that the region of the P type in the transistor portion 70 increases to increase the hole injection, thereby increasing the switching loss Err during the reverse recovery. By including the thinning region 60, it is possible for the semiconductor device 100 to easily reduce the switching loss Err during the reverse recovery even when the ratio α becomes great. In particular, when the ratio α exceeds 1.5, a reduction effect of the switching loss Err during the reverse recovery in the graph G100 of the semiconductor device 100 becomes remarkable, in comparison with the graph Gc of the semiconductor device in the comparative example. The ratio α may be 1.5 or more, may be 2.0 or more, may be 2.5 or more, or may be 3.0 or more. The ratio α may be 20 or less, may be 10 or less, may be 7.0 or less, may be 5.0 or less, or may be 3.0 or less.

FIG. 6B shows dependence of a saturation current Isat of a collector current, on the ratio α. The vertical axis represents the saturation current Isat (a.u.), of the collector current, and the horizontal axis represents the ratio α. When the ratio α of the interval P12 to the length L65 of the non-thinning region 65 in the trench extension direction, becomes great, the saturation current Isat decreases. The decrease in the saturation current Isat enhances short-circuit withstand capability.

By including the thinning region 60, it is possible for the semiconductor device 100 to increase the ratio α to enhance the short circuit withstand capability, and to suppress the switching loss Err during the reverse recovery. In addition, by including the trench contact portion 58, it is possible for the semiconductor device 100 to further enhance the latch-up withstand capability.

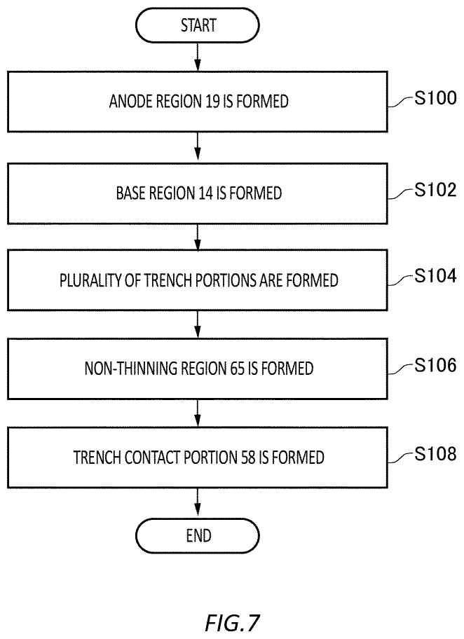

FIG. 7 shows an example of a method for manufacturing the semiconductor device 100. The present example shows an example of the method for manufacturing the semiconductor device 100, and order of respective steps and the like may be changed as appropriate.

Step S100 and step S102 are examples of stages of forming the thinning region 60. In step S100, the anode region 19 is formed above the drift region 18. In step S102, the base region 14 is formed above the drift region 18. When the base region 14 and the anode region 19 have the same doping concentration, the base region 14 and the anode region 19 may be formed simultaneously in a common step.

The base region 14 and the anode region 19 may be formed by selectively ion-implanting the dopant of the second conductivity type according to the structure of the thinning region 60. In the present example, the base region 14 is formed after the anode region 19 is formed; however, the anode region 19 may be formed after the base region 14 is formed. The region with a lower doping concentration in the base region 14 and the anode region 19 may be formed first. For the thinning region 60, after the anode region 19 is formed in the transistor portion 70 and the diode portion 80, the base region 14 may be formed by ion-implanting the dopant of the second conductivity type into the anode region 19 of the transistor portion 70. The doping concentration of the base region 14 may be higher than the doping concentration of the anode region 19.

In step S104, the plurality of trench portions are formed at the front surface 21 of the semiconductor substrate 10. The dummy trench portion 30 and the gate trench portion 40 may be formed simultaneously in a common step, or the dummy trench portion 30 and the gate trench portion 40 may be formed separately. The thinning region 60 may be formed after the plurality of trench portions are formed.

In step S106, the non-thinning region 65 is formed at the front surface 21 of the semiconductor substrate 10. The non-thinning region 65 is formed in the mesa portion 71 between the plurality of trench portions. The contact region 15 may be formed after the emitter region 12 is formed, or the emitter region 12 may be formed after the contact region 15 is formed. When the non-thinning region 67 is formed, the non-thinning region 67 may be formed simultaneously with the non-thinning region 65.

In step S108, the trench contact portion 58 is formed. The plug region 13 may be formed by ion-implanting the dopant of the second conductivity type into a lower end of the contact hole 54, after the contact hole 54 of the trench contact portion 58 is formed. The trench contact portion 58 may be formed by filling the contact hole 54 with the barrier metal 53 and the plug portion 59, after the plug region 13 is formed.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such changes or improvements are made may be included in the technical scope of the present invention.

It should be noted that each process of the operations, procedures, steps, stages, and the like performed by the device, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: semiconductor substrate; 12: emitter region; 13: plug region; 14: base region; 15: contact region; 16: accumulation region; 17: well region; 18: drift region; 19: anode region; 20: buffer region; 21: front surface; 22: collector region; 23: back surface; 24: collector electrode; 25: connection portion; 30: dummy trench portion; 31: extension part; 32: dummy dielectric film; 33: connection part; 34: dummy conductive portion; 38: interlayer dielectric film; 40: gate trench portion; 41: extension part; 42: gate dielectric film; 43: connection part; 44: gate conductive portion; 50: gate metal layer; 51: gate runner portion; 52: emitter electrode; 53: barrier metal; 54: contact hole; 55: contact hole; 56: contact hole; 58: trench contact portion; 59: plug portion; 60: thinning region; 61: first thinning portion; 62: second thinning portion; 65: non-thinning region; 67: non-thinning region; 70: transistor portion; 71: mesa portion; 78: boundary; 80: diode portion; 81: mesa portion; 82: cathode region; 90: boundary region; 91: mesa portion; 100: semiconductor device; 102: end side; 112: gate pad; 130: gate runner; 160: active portion; 162: first conductivity type region; 170: edge termination structure portion.

What is claimed is:

1. A semiconductor device including a transistor portion and a diode portion, the semiconductor device comprising:
a drift region of a first conductivity type which is provided in a semiconductor substrate;
a plurality of trench portions which extend in a predetermined trench extension direction, on a front surface side of the semiconductor substrate, wherein
the transistor portion has
a base region of a second conductivity type which is provided above the drift region,
a plurality of emitter regions of the first conductivity type which are discretely provided in a trench extension direction, and each of which has a higher doping concentration than the drift region,
a contact region of the second conductivity type which has a higher doping concentration than the base region,
a trench contact portion which is provided to extend from a front surface of the semiconductor substrate in a depth direction of the semiconductor substrate, in a mesa portion between two adjacent trench portions, among the plurality of trench portions, and
a thinning region which is provided between two adjacent emitter regions in the trench extension direction, among the plurality of emitter regions, and which has a lower doping concentration of the second conductivity type than the contact region.

2. The semiconductor device according to claim 1, wherein
the thinning region is the base region.

3. The semiconductor device according to claim 1, wherein
the thinning region has
a first thinning portion which is provided between the two adjacent emitter regions, and which is provided in contact with the contact region at the front surface of the semiconductor substrate, and
a second thinning portion which is provided between the two adjacent emitter regions, and which is provided in contact with the first thinning portion at the front surface of the semiconductor substrate, and which has a doping concentration different from that of the first thinning portion.

4. The semiconductor device according to claim 3, wherein
the first thinning portion includes a plurality of first thinning portions, and
the second thinning portion is provided between two adjacent first thinning portions in the trench extension direction, among the plurality of first thinning portions, at the front surface.

5. The semiconductor device according to claim 3, wherein
the first thinning portion is the base region, and
the second thinning portion has the first conductivity type with a lower doping concentration than the emitter region.

6. The semiconductor device according to claim 5, wherein
the second thinning portion is the drift region.

7. The semiconductor device according to claim 3, wherein
the first thinning portion is the base region, and
the second thinning portion has the second conductivity type with a lower doping concentration than the base region.

8. The semiconductor device according to claim 7, wherein
the diode portion has an anode region of the second conductivity type which is provided above the drift region, and
the second thinning portion is the anode region.

9. The semiconductor device according to claim 1, wherein
the contact region has a plurality of contact regions, and
the plurality of contact regions are provided at both ends of the emitter regions in the trench extension direction, and are in contact with the emitter regions at the front surface.

10. The semiconductor device according to claim 3, wherein
the contact region is provided between the emitter region and the first thinning portion which are adjacent to each other in the trench extension direction, and at the front surface, one end of the contact region is in contact with the emitter region, and another end of the contact region is in contact with the first thinning portion.

11. The semiconductor device according to claim 10, wherein
the first thinning portion is provided below the contact region, and
a length of the first thinning portion provided at the front surface in the trench extension direction is greater than or equal to a thickness of the first thinning portion provided below the contact region in the depth direction of the semiconductor substrate.

12. The semiconductor device according to claim 11, wherein
the length of the first thinning portion provided at the front surface in the trench extension direction is 0.1 μm or more and 2.0 μm or less.

13. The semiconductor device according to claim 3, wherein
at the front surface, a length of the second thinning portion in the trench extension direction is greater than a length of the first thinning portion in the trench extension direction.

14. The semiconductor device according to claim 3, wherein
at the front surface, a length of the second thinning portion in the trench extension direction is greater than a length of the emitter region in the trench extension direction.

15. The semiconductor device according to claim 3, comprising:
an interlayer dielectric film which is provided above the first thinning portion and the second thinning portion, and which covers both of the first thinning portion and the second thinning portion that are provided at the front surface.

16. The semiconductor device according to claim 15, wherein
the interlayer dielectric film has a contact hole, and
in a top view, the trench contact portion is provided in a region where the contact hole is provided, and in the top view, a region where the contact hole is not provided is a trench contact non-forming region where the trench contact portion is not provided.

17. The semiconductor device according to claim 1, wherein
a ratio α of an interval between the two adjacent emitter regions in the trench extension direction, to a length, in the trench extension direction, of a non-thinning region in which one or more emitter regions and one or more contact regions are continuously formed is 1.5 or more and 20 or less.

18. The semiconductor device according to claim 1, which does not have a lifetime killer region on the front surface side from a center in the depth direction of the semiconductor substrate.

19. A method for manufacturing a semiconductor device including a transistor portion and a diode portion, the method for manufacturing a semiconductor device comprising:
forming a base region of a second conductivity type above a drift region of a first conductivity type which is provided in a semiconductor substrate;
forming a plurality of trench portions which extend in a predetermined trench extension direction, on a front surface side of the semiconductor substrate;
forming a plurality of emitter regions of the first conductivity type, each of which has a higher doping concentration than the drift region, discretely in a trench extension direction;
forming a contact region of the second conductivity type which has a higher doping concentration than the base region;
forming a trench contact portion, in the transistor portion, to extend from a front surface of the semiconductor substrate in a depth direction of the semiconductor substrate, in a mesa portion between two adjacent trench portions, among the plurality of trench portions; and
forming a thinning region which has a lower doping concentration of the second conductivity type than the contact region, between two adjacent emitter regions in the trench extension direction, among the plurality of emitter regions.

20. The method for manufacturing the semiconductor device according to claim 19, wherein
the thinning region includes the base region, and
the forming the thinning region includes forming the base region, by forming an anode region in the transistor portion and the diode portion, and then ion-implanting a dopant of the second conductivity type into the anode region of the transistor portion.
